(19) United States
(12) Patent Application Publication
(10) Pub. No.: US 2022/0013381 A1
(43) Pub. Date: Jan. 13, 2022

(54) MASS TRANSFER APPARATUS, METHOD, AND DEVICE

(71) Applicant: CHONGQING KONKA PHOTOELECTRIC TECHNOLOGY RESEARCH INSTITUTE CO., LTD., Chongqing (CN)

(72) Inventors: Ming Ta TSAI, Chongqing (CN); Ruilin XU, Chongqing (CN)

(21) Appl. No.: 17/397,085

(22) Filed: Aug. 9, 2021

Related U.S. Application Data
(63) Continuation of application No. PCT/CN2020/100877, filed on Jul. 8, 2020.

(51) Int. Cl. H01L 21/67; H01L 27/15; H01L 25/075; H05K 13/04

(52) U.S. Cl. CPC H01L 21/67144; H01L 27/156; H05K 13/0408; H05K 13/0406; H01L 25/0753

(57) ABSTRACT

A mass transfer apparatus, method, and device are provided. The mass transfer apparatus includes a rotating disk, a drive member, a first transfer head, a second transfer head, and a third transfer head. The rotating disk has a first surface and a second surface opposite to the first surface. The first surface is divided into a first region, a second region, a third region, and a fourth region. The drive member is connected to the second surface and configured to drive the rotating disk to move or rotate. The first transfer head is located in the first region, the second transfer head is located in the second region, and the third transfer head is located in the third region. The first transfer head and the second transfer head is symmetric about the first line, and the second transfer head and the third transfer head is symmetric about the second line.

### CROSS-REFERENCE TO RELATED APPLICATION(S)

This application is a continuation of International Application No. PCT/CN2020/100877, filed on Jul. 8, 2020, the disclosure of which is hereby incorporated by reference in its entirety.

### TECHNICAL FIELD

This disclosure relates to the technical field of transferring, and in particular to a mass transfer apparatus, a mass transfer method, and a mass transfer device.

### BACKGROUND

A display backplane includes several pixel areas, each of which includes a red LED chip, a blue LED chip, and a green LED chip. In the manufacturing process of a display, it is necessary to transfer red LED chips, green LED chips, and blue LED chips from their respective growth substrates to the display backplane. In order for transfer of these three types of chips, an existing transfer apparatus requires to transfer multiple times, which leads to higher time cost and is disadvantageous for mass production of the display.

### SUMMARY

The disclosure aims to provide a mass transfer apparatus, a mass transfer method, and a mass transfer device, so as to solve the technical problem that the existing transfer apparatus requires to transfer red, green, and blue LED chips multiple times, which leads to higher time cost and is disadvantageous for mass production of the display.

The disclosure provides a mass transfer apparatus. The mass transfer apparatus includes a rotating disk, a drive member, a first transfer head, a second transfer head, and a third transfer head. The rotating disk has a first surface and a second surface opposite to the first surface. The first surface is divided by a first line and a second line perpendicular to the first line into a first region, a second region, a third region, and a fourth region arranged clockwise. The drive member is connected to the second surface and configured to drive the rotating disk to move or rotate. The first transfer head is located in the first region, the second transfer head is located in the second region, and the third transfer head is located in the third region. The first transfer head and the second transfer head is symmetric about the first line, and the second transfer head and the third transfer head is symmetric about the second line. As such, when the mass transfer apparatus of the disclosure is used to transfer red, green, and blue LED chips, these three types of LED chips can be transferred simultaneously to a display backplane by a single “transport” process, which saves time cost. Given that the display backplane has four transfer regions, the transfer of the three types of LED chips to the four transfer regions may only require four transfer processes, which will significantly save time of mass transfer and facilitate mass production of the display.

In an implementation, the mass transfer apparatus further includes a rotating component. The rotating component is connected between the drive member and the second surface. The drive member is configured to drive, through the rotating component, the rotating disk to rotate. The rotating component is configured to transmit a torque of the drive member to the rotating disk, so as to drive the rotating disk to move or rotate.

In an implementation, the first transfer head is movably connected with the first region, the second transfer head is movably connected with the second region, and the third transfer head is movably connected with the third region. As such, by adjusting a position of the first transfer head on the first region, a position of the second transfer head on the second region, and a position of the third transfer head on the third region, the first transfer head can be controlled to accurately pick up (or adsorb) red LED chips on a first temporary substrate, the second transfer head can be controlled to pick up green LED chips on a second temporary substrate, and the third transfer head can be controlled to pick up blue LED chips on a third temporary substrate. Moreover, the first transfer head can be controlled to transfer the red LED chips to a corresponding transfer region of the display backplane, the second transfer head can be controlled to transfer the green LED chips to a corresponding transfer region of the display backplane, and the third transfer head can be controlled to transfer the blue LED chips to a corresponding transfer region of the display backplane.

In an implementation, the first transfer head has a first transfer surface away from the first surface, the second transfer head has a second transfer surface away from the first surface, the third transfer head has a third transfer surface away from the first surface. The first transfer surface, the second transfer surface, and the third transfer surface have a same shape and area. As such, each of the first transfer head, the second transfer head, and the third transfer head can transfer the same number of chips each time. The number of chips transferred to the display backplane can be accurately controlled, such that each transfer region has the same number of red, greed, and blue chips, thus improving yield of the display backplane.

In an implementation, the first transfer surface is square, the second transfer surface is square, and the third transfer surface is square.

In an implementation, a first distance between a center of the first transfer head and a center of the second transfer head is equal to a second distance between the center of the second transfer head and a center of the third transfer head. As such, after the rotating disk is rotated by a first angle, a second angle, or a third angle, positions of the first transfer head, the second transfer head, and the third transfer head can be exchanged with each other. Therefore, the first transfer head, the second transfer head, and the third transfer head can align with corresponding transfer regions of the display backplane, thus improving accuracy of positions of chips and improving yield of the display backplane.

In an implementation, the first surface is symmetric about the first line and the first surface is symmetric about the second line. As such, the first surface is central symmetric. The fire region, the second region, the third region, and the fourth region have a same shape, which is convenient for installation and arrangement of the first transfer head, the second transfer head, and the third transfer head.

In an implementation, the first surface is circular or square.

The disclosure provides a mass transfer method. The mass transfer method includes the following. A mass transfer apparatus is provided. The mass transfer apparatus includes a first transfer head, a second transfer head, and a third transfer head. Red LED chips are picked up with the first transfer head, green LED chips are picked up with the second transfer head, and blue LED chips are picked up with the blue LED chips. A display backplane is provided. The display backplane has a first transfer region, a second transfer region, a third transfer region, and a fourth transfer region. The first transfer head, the second transfer head, and the third transfer head are moved and/or rotated in such a manner that each of the first transfer region, the second transfer region, the third transfer region, and the fourth transfer region has red LED chips, green LED chips, and blue LED chips thereon. As such, the mass transfer method of the disclosure uses the first transfer head, the second transfer head, and the third transfer head to transfer the red LED chips, the green LED chips, and the blue LED chips. In this way, transfer efficiency can be significantly improved, thus greatly saving time of the mass transfer and facilitating mass production of the display.

In an implementation, the red LED chips are picked up with the first transfer head, the green LED chips are picked up with the second transfer head, and the blue LED chips are picked up with the third LED chips as follows. A first temporary substrate, a second temporary substrate, and a third temporary substrate are provided. The first temporary substrate is provided with red LED chips arranged thereon in an array, the second temporary substrate is provided with green LED chips arranged thereon in an array, the third temporary substrate is provided with blue LED chips arranged thereon in an array. The first transfer head, the second transfer head, and the third transfer head are adjusted to align the first transfer head with the first temporary substrate, align the second transfer head with the second temporary substrate, and align the third transfer head with the third temporary substrate. The first transfer head is driven to move towards the first temporary substrate, the second transfer head is driven to move towards the second temporary substrate, and the third transfer head is driven to move towards the third temporary substrate, such that the first transfer head picks up the red LED chips on the first temporary substrate, the second transfer head picks up the green LED chips on the second temporary substrate, and the third transfer head picks up the blue LED chips on the third temporary substrate. As such, before picking up the red LED chips, the green LED chips, and the blue LED chips, the first transfer head is adjusted to be aligned with the first temporary substrate, the second transfer head is adjusted to be aligned with the second temporary substrate, and the third transfer head is adjusted to be aligned with the third temporary substrate. In this way, the first transfer head can accurately pick up the red LED chips, the second transfer head can accurately pick up the green LED chips, and the third transfer head can accurately pick up the blue LED chips.

In an implementation, moving and/or rotating the first transfer head, the second transfer head, and the third transfer head in such a manner that each of the first transfer region, the second transfer region, the third transfer region, and the fourth transfer region has red LED chips, green LED chips, and blue LED chips includes the following. The first transfer head, the second transfer head, and the third transfer head are driven to move towards the display backplane, such that the first transfer head transfers the red LED chips to the first transfer region of the display backplane, the second transfer head transfers the green LED chips to the second transfer region of the display backplane, and the third transfer head transfers the blue LED chips to the third transfer region of the display backplane. This process is a first transfer process of the red LED chips, green LED chips, and blue LED chips.

In an implementation, moving and/or rotating the first transfer head, the second transfer head, and the third transfer head in such a manner that each of the first transfer region, the second transfer region, the third transfer region, and the fourth transfer region has red LED chips, green LED chips, and blue LED chips further includes the following. The first transfer head, the second transfer head, and the third transfer head are driven to rotate by a first angle counterclockwise, and then the first transfer head, the second transfer head, and the third transfer head are driven to move towards the display backplane, such that the first transfer head transfers the red LED chips to the second transfer region of the display backplane, the second transfer head transfers the green LED chips to the third transfer region of the display backplane, and the third transfer head transfers the blue LED chips to the fourth transfer region of the display backplane. This process is a second transfer process of the red LED chips, green LED chips, and blue LED chips.

In an implementation, moving and/or rotating the first transfer head, the second transfer head, and the third transfer head in such a manner that each of the first transfer region, the second transfer region, the third transfer region, and the fourth transfer region has red LED chips, green LED chips, and blue LED chips further includes the following. The first transfer head, the second transfer head, and the third transfer head are driven to rotate by a second angle counterclockwise, and then the first transfer head, the second transfer head, and the third transfer head are driven to move towards the display backplane, such that the first transfer head transfers the red LED chips to the third transfer region of the display backplane, the second transfer head transfers the green LED chips to the fourth transfer region of the display backplane, and the third transfer head transfers the blue LED chips to the first transfer region of the display backplane. This process is a third transfer process of the red LED chips, green LED chips, and blue LED chips.

In an implementation, moving and/or rotating the first transfer head, the second transfer head, and the third transfer head in such a manner that each of the first transfer region, the second transfer region, the third transfer region, and the fourth transfer region has red LED chips, green LED chips, and blue LED chips further includes the following. The first transfer head, the second transfer head, and the third transfer head are driven to rotate by a third angle counterclockwise, and then the first transfer head, the second transfer head, and the third transfer head are driven to move towards the display backplane, such that the first transfer head transfers the red LED chips to the fourth transfer region of the display backplane, the second transfer head transfers the green LED chips to the first transfer region of the display backplane, and the third transfer head transfers the blue LED chips to the second transfer region of the display backplane. This process is a fourth transfer process of the red LED chips, green LED chips, and blue LED chips.

In an implementation, the mass transfer apparatus further includes a rotating disk. The first transfer head, the second transfer head, and the third transfer head are disposed at a same side of the rotating disk and spaced apart. The first transfer head, the second transfer head, and the third transfer head are moved and/or rotated as follows. The rotating disk is driven to move and/or rotate, so as to drive the first transfer head, the second transfer head, and the third transfer head to move and/or rotate. The process of driving the rotating disk to drive the first transfer head, the second transfer head, and the third transfer head to move and/or rotate is simple and easy to implement.

In an implementation, the mass transfer method further includes the following. A first initial substrate and a first growth substrate are provided, and red LED chips on the first growth substrate are transferred to the first initial substrate to form the first temporary substrate. A second initial substrate and a second growth substrate are provided, and green LED chips on the second growth substrate are transferred to the second initial substrate to form the second temporary substrate. A third initial substrate and a third growth substrate are provided, and blue LED chips on the third growth substrate are transferred to the third initial substrate to form the third temporary substrate.

In an implementation, each of the red LED chips is axisymmetric, each of the green LED chips is axisymmetric, and each of the blue LED chips is axisymmetric. As such, after the first transfer head, the second transfer head, and the third transfer head are rotated by the first angle, the second angle, and the third angle, the red, green, and blue LED chips as rotated can be positioned on respective transfer regions smoothly without being skew or uneven.

In an implementation, the first angle is 90 degrees, the second angle is 180 degrees, and the third angle is 270 degrees.

The disclosure provides a mass transfer device. The mass transfer device includes a first transfer head, a second transfer head, and a third transfer head. The first transfer head is configured to pick up red LED chips. The second transfer head is configured to pick up green LED chips. The third transfer head is configured to pick up blue LED chips. The mass transfer device further includes a drive member. The drive member is configured to move and/or rotate the first transfer head, the second transfer head, and the third transfer head in such a manner that each of a first transfer region, a second transfer region, a third transfer region, and a fourth transfer region of a display backplane has red LED chips, green LED chips, and blue LED chips. As such, the mass transfer device of the disclosure uses the first transfer head, the second transfer head, and the third transfer head to transfer the red LED chips, the green LED chips, and the blue LED chips. In this way, transfer efficiency can be significantly improved, thus greatly saving time of the mass transferring and facilitating mass production of the display.

### BRIEF DESCRIPTION OF THE DRAWINGS

FIG. 1 to FIG. 6 are schematic diagrams illustrating a traditional method for transferring red LED chips.

FIG. 7 to FIG. 12 are schematic diagrams illustrating a traditional method for transferring green LED chips.

FIG. 13 to FIG. 18 are schematic diagrams illustrating a traditional method for transferring blue LED chips.

FIG. 19 is a schematic structural diagram of a mass transfer apparatus of embodiments of the disclosure.

FIG. 20 is a bottom view of a structure of the mass transfer apparatus of FIG. 19.

FIG. 21 is a schematic structural diagram illustrating the mass transfer apparatus of FIG. 19 being aligned with a first temporary substrate, a second temporary substrate, and a third temporary substrate.

FIG. 22 is a bottom view of an initial structure of the mass transfer apparatus of FIG. 19.

FIG. 23 is a first schematic structure diagram of a display backplane.

FIG. 24 is a bottom view of the structure of the mass transfer apparatus of FIG. 19 after rotated by a first angle.

FIG. 25 is a second schematic structure diagram of the display backplane.

FIG. 26 is a bottom view of the structure of the mass transfer apparatus of FIG. 19 after rotated by a second angle.

FIG. 27 is a third schematic structure diagram of the display backplane.

FIG. 28 is a bottom view of the structure of the mass transfer apparatus of FIG. 19 after rotated by a third angle.

FIG. 29 is a fourth schematic structure diagram of a display backplane.

FIG. 30 is a schematic flow chart of a mass transfer method of embodiments of the disclosure.

FIG. 31 is a schematic structural diagram of a mass transfer system of embodiments of the disclosure.

### DETAILED DESCRIPTION

The technical solutions in embodiments of the present disclosure will be clearly and completely described below in conjunction with the accompanying drawings in the embodiments of the present disclosure. Obviously, the described embodiments are only a part rather than all of the embodiments of the present disclosure. Based on the embodiments of the present disclosure, all other embodiments obtained by those of ordinary skill in the art without creative work shall fall within the protection scope of the present disclosure.

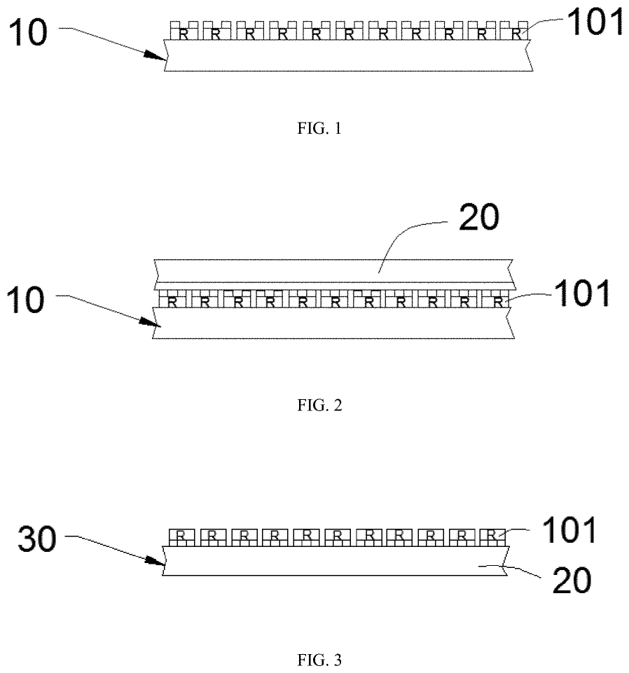

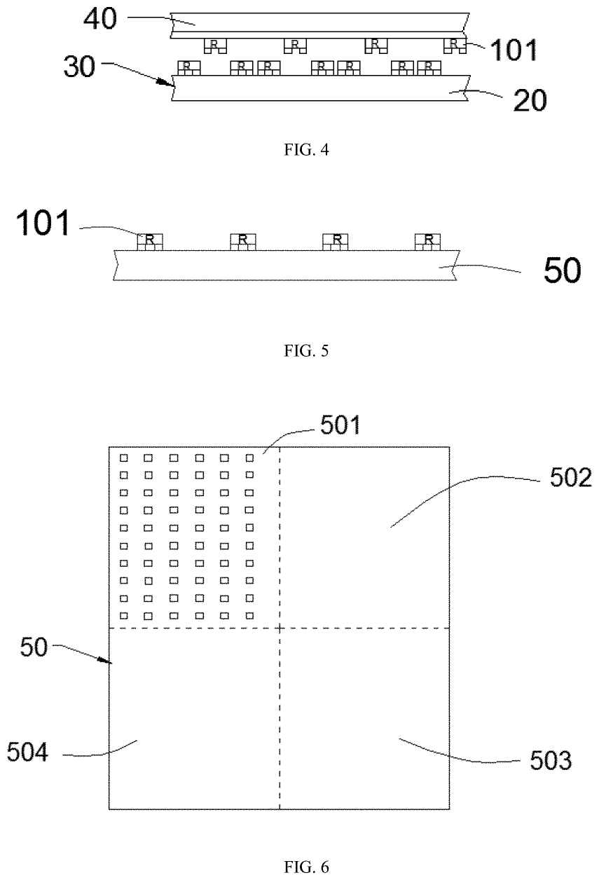

Referring to FIG. 1 to FIG. 6, in a traditional transfer method, a first growth substrate 10 (FIG. 1) is provided. The first growth substrate 10 has multiple red LED chips 101 arranged thereon in an array (growth substrate for red LED chips). The red LED chips 101 are adhered to a first initial substrate 20 by an adhesive layer on a surface of the first initial substrate 20, so as to form a first temporary substrate 30 (FIG. 2). After peeling the first growth substrate 10 through laser, the first temporary substrate 30 as shown in FIG. 3 is obtained. A first transfer substrate 40 selectively transfers the red LED chips 101 on the first temporary substrate 30 to a first transfer region 501 of a display backplane 50, and the display backplane 50 as shown in FIG. 4 to FIG. 6 is obtained.

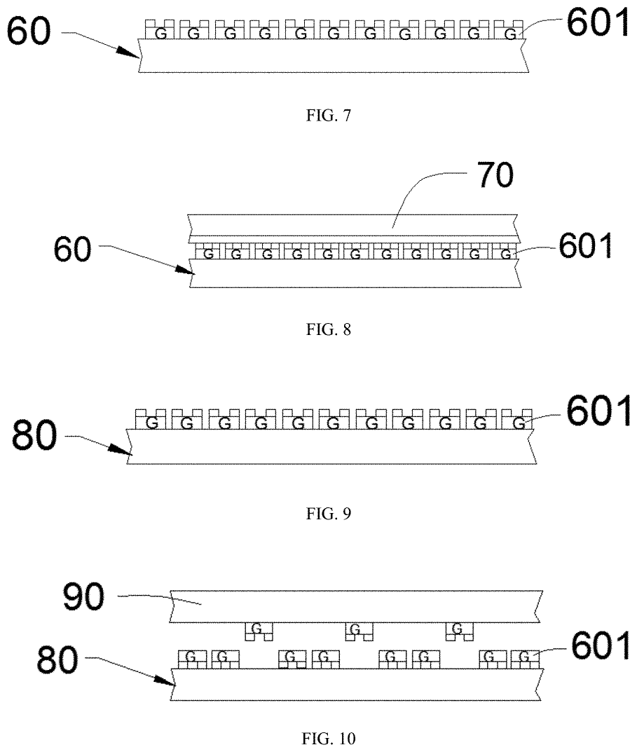

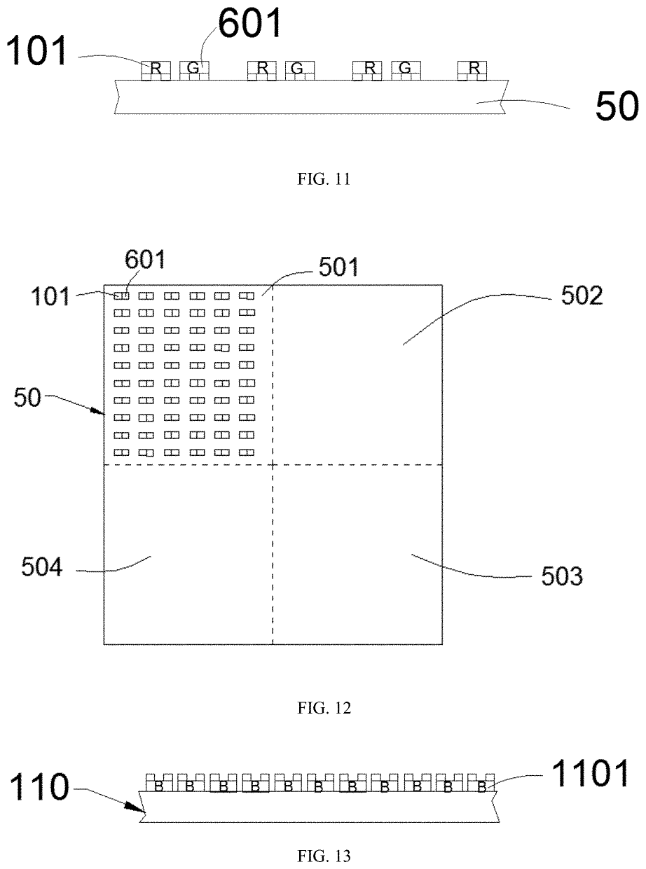

Referring to FIG. 7 to FIG. 12, green LED chips 601 can be transferred in a manner similar to that described above. A second growth substrate 60 (FIG. 7) is provided. The second growth substrate 60 has multiple green LED chips 601 arranged thereon in an array (growth substrate for green LED chips). The green LED chips 601 are adhered to a second initial substrate 70 by an adhesive layer on a surface of the second initial substrate 70, so as to form a second temporary substrate 80 (FIG. 8). After peeling the second growth substrate 60 through laser, the second temporary substrate 80 as shown in FIG. 9 is obtained. A second transfer substrate 90 selectively transfers the green LED chips 601 on the second temporary substrate 80 to the first transfer region 501 of the display backplane 50, and the display backplane 50 as shown in FIG. 10 to FIG. 12 is obtained. In one pixel area on each transfer region, a green LED chip 601 is adjacent to a red LED chip 101.

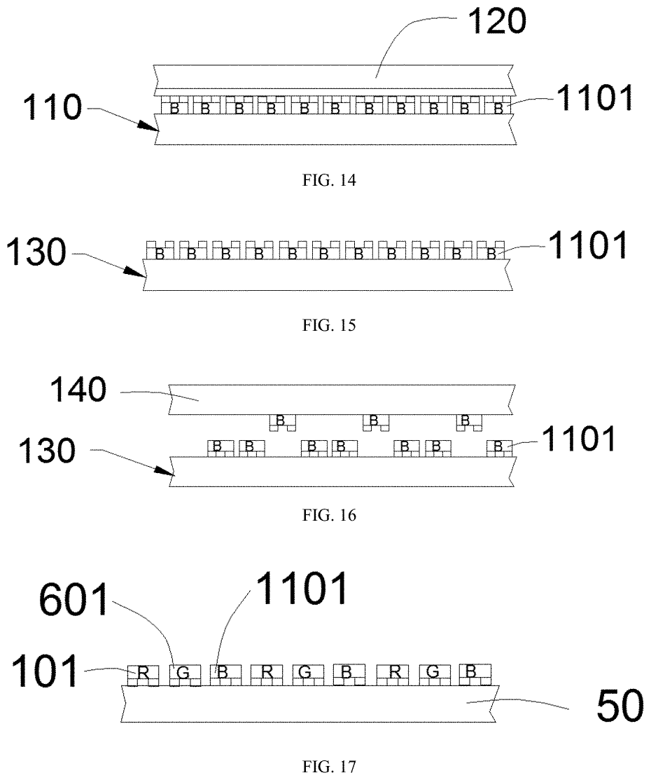

Referring to FIG. 13 to FIG. 18, blue LED chips 1101 can be transferred in a manner similar to that described above. A third growth substrate 110 (FIG. 13) is provided. The third growth substrate 110 has multiple blue LED chips 1101 arranged thereon in an array (growth substrate for blue LED chips). The blue LED chips 1101 are adhered to a third initial substrate 120 by an adhesive layer on a surface of the third initial substrate 120, so as to form a third temporary substrate 130 (FIG. 14). After peeling the third growth substrate 110 through laser, the third temporary substrate 130 as shown in FIG. 15 is obtained. A third transfer substrate 140 selectively transfers the blue LED chips 1101 on the third temporary substrate 130 to the first transfer region 501 of the display backplane 50, and the display backplane 50 as shown in FIG. 16 to FIG. 18 is obtained. In one pixel area on each transfer region, a blue LED chip is adjacent to a green LED chip 601, and the green LED chip 601 is located between a red LED chip 101 and the blue LED chip 1101.

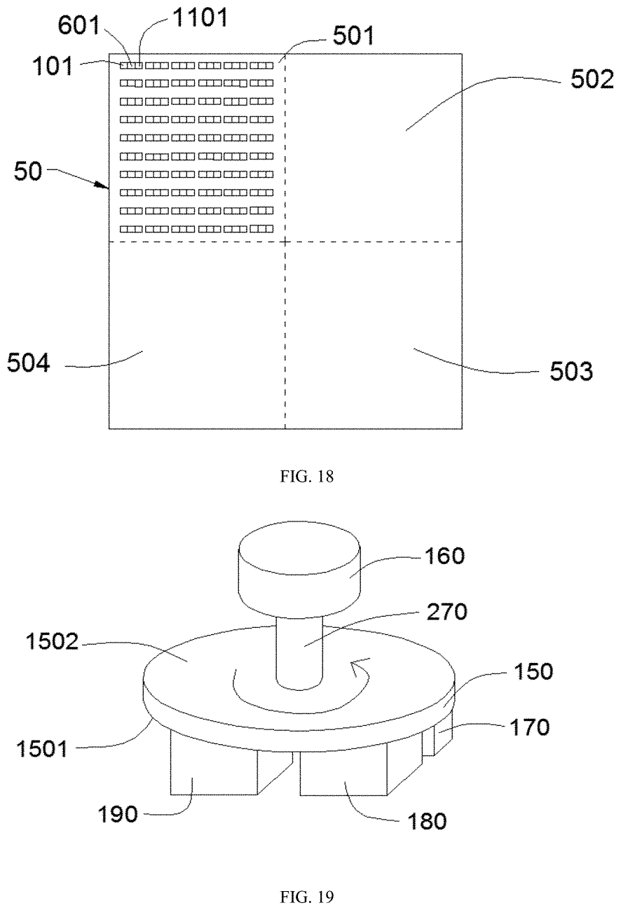

As can be seen from the description above, the red, green, blue LED chips are transferred to the first transfer region 501 of the display backplane 50 by three repetitive “transport” processes. Given that the display backplane includes four transfer regions (as shown in FIG. 6, FIG. 12, and FIG. 18), such as a first transfer region 501, a second transfer region 502, a third transfer region 503, and a fourth transfer region 504, it will require 3*4 repetitive “transport” processes for the transfer substrate to transfer the red, green, blue LED chips to the four transfer regions, which costs a lot of time and is unfavorable for mass production of the display.

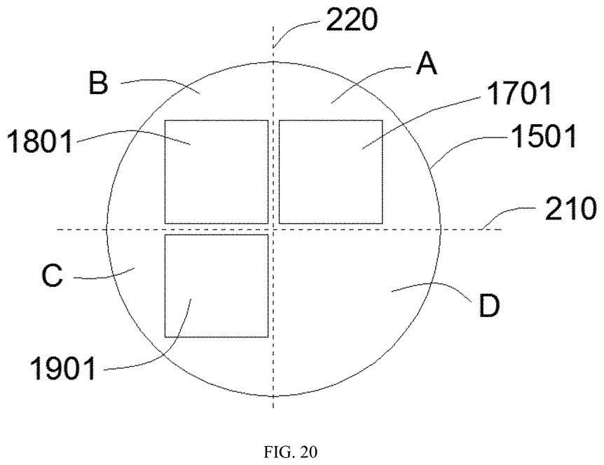

Based on the problem above-described, the disclosure provides a mass transfer apparatus. Referring to FIG. 19 to FIG. 20, the mass transfer apparatus includes a rotating disk 150, a drive member 160, a first transfer head 170, a second transfer head 180, and a third transfer head 190.

The rotating disk 150 has a first surface 1501 and a second surface 1502 opposite to the first surface 1501. The first surface 1501 is divided by a first line 210 and a second line 220 perpendicular to the first line 210 into a first region A, a second region B, a third region C, and a fourth region D arranged clockwise.

The drive member 160 is connected to the second surface 1502 and configured to drive the rotating disk to move or rotate.

The first transfer head 170 is located in the first region A, the second transfer head 180 is located in the second region B, and the third transfer head 190 is located in the third region C. The first transfer head 170 and the second transfer head 180 are symmetric about the first line 210, and the second transfer head 180 and the third transfer head 190 are symmetric about the second line 220.

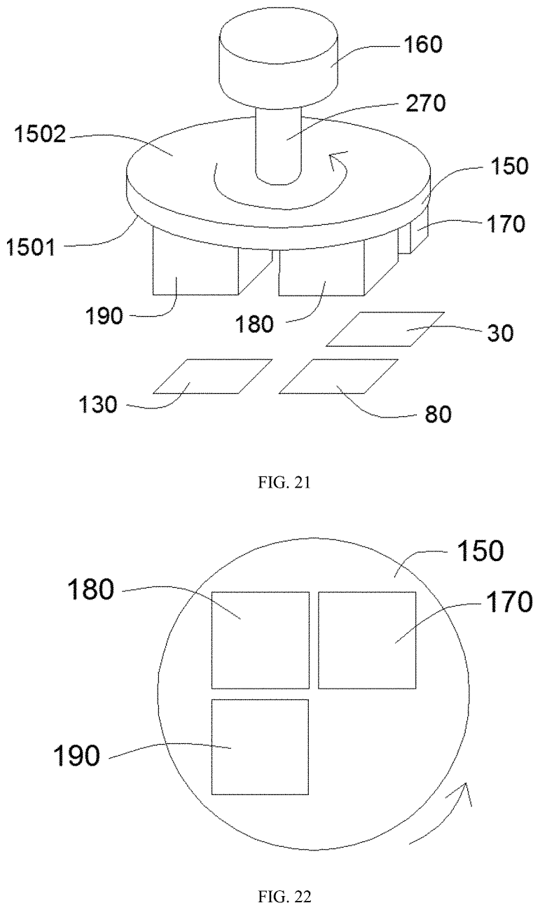

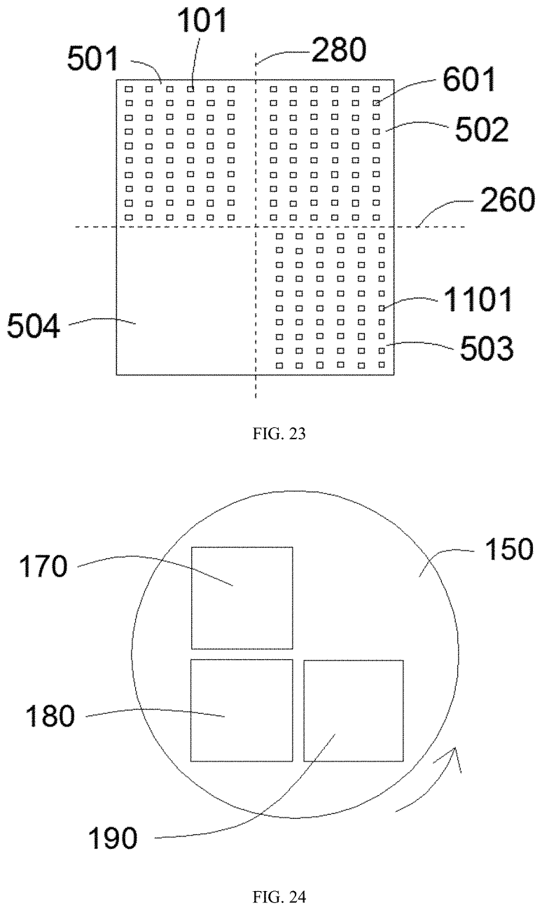

As such, in a transfer process of red, green, and blue LED chips using the mass transfer apparatus, the first transfer head 170 may be aligned with a first temporary substrate 30 with red LED chips 101 arranged thereon in an array, the second transfer head 180 may be aligned with a second temporary substrate 80 with green LED chips 601 arranged thereon in an array, and the third transfer head 190 may be aligned with a third temporary substrate 130 with blue LED chips 1101 arranged thereon in an array (FIG. 21). The rotating disk 150 is driven to move towards the first temporary substrate 30, the second temporary substrate 80, and the third temporary substrate 130, such that the first transfer head 170 picks up red LED chips 101 on a first temporary substrate 30, the second transfer head 180 picks up green LED chips 601 on a second temporary substrate 80, and the third transfer head 190 picks up blue LED chips 1101 on a third temporary substrate 130 (FIG. 22). The rotating disk 150 is driven to move towards the display backplane 50, such that the first transfer head 170 transfers the red LED chips 101 to the first transfer region 501 of the display backplane 50, the second transfer head 180 transfers the green LED chips 601 to the second transfer region 502 of the display backplane 50, and the third transfer head 190 transfers the blue LED chips 1101 to the third transfer region 503 of the display backplane 50 (FIG. 23).

In this way, a single “transport” process may realize simultaneous transfer of red, green, and blue chips to the display backplane 50, which saves time. It can be understood that the mass transfer apparatus may transfer all of the red, green, and blue chips to one transfer region, or transfer each type of the red, green, and blue chips to one corresponding transfer region. After the first transfer head 170 picks up the red LED chips 101, the second transfer head 180 picks up the green LED chips 601, and the third transfer head 190 picks up the blue LED chips 1101, the drive member 160 may drive the rotating disk 150 to reset and then move towards the display backplane 50. Alternatively, the rotating disk 150 moves towards the display backplane 50 directly without reset.

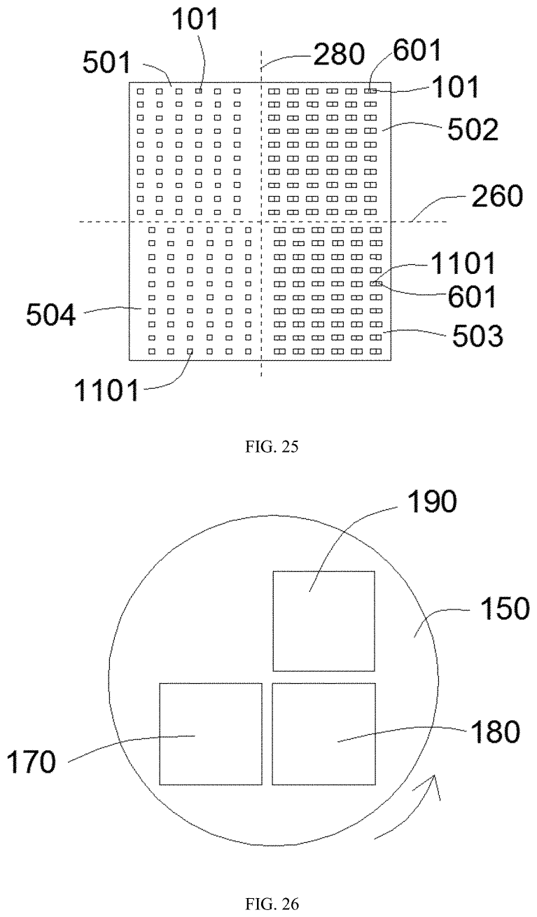

Referring FIG. 24 to FIG. 25, the display backplane 50 may include four transfer regions. In this case, the rotating disk 150 may be driven to reset after a transfer process is finished, and then the first transfer head 170 picks up red LED chips 101 on the first temporary substrate 30, the second transfer head 180 picks up green LED chips 601 on the second temporary substrate 80, and the third transfer head 190 picks up blue LED chips 1101 on the third temporary substrate 130 again. Then the rotating disk 150 is driven to rotate by a first angle counterclockwise (FIG. 24). After that, the rotating disk 150 is driven to move towards the display backplane 50, so that the first transfer head 170 transfers the red LED chips 101 to the second transfer region 502 of the display backplane 50, the second transfer head 180 transfers the green LED chips 601 to the third transfer region 503 of the display backplane 50, and the third transfer head 190 transfers the blue LED chips 1101 to the fourth transfer region 504 of the display backplane 50 (FIG. 25). It can be understood that the display backplane 50 is divided by a third line 260 and a fourth line 280 perpendicular to the third line 260 into the first transfer region 501, the second transfer region 502, the third transfer region 503, and the fourth transfer region 504 arranged clockwise.

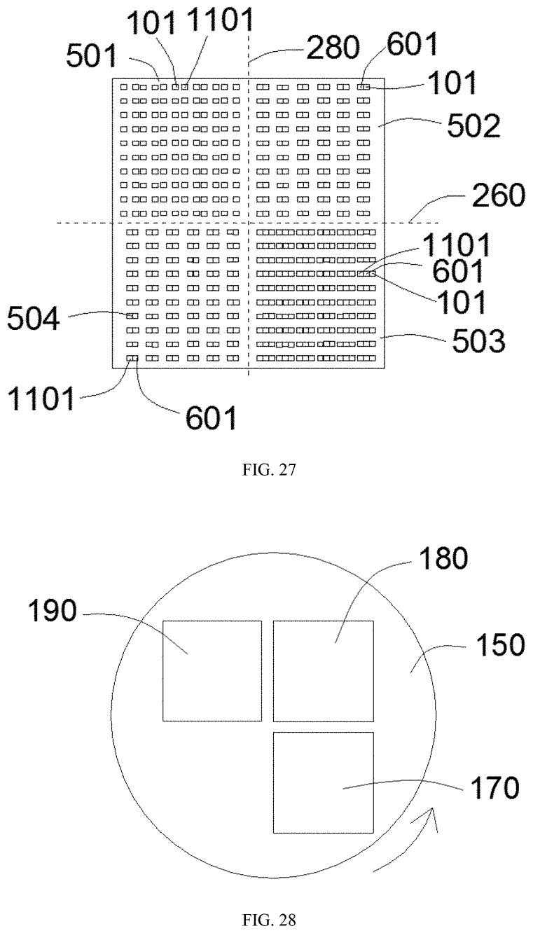

Referring FIG. 26 to FIG. 27, the rotating disk 150 may be driven to reset again, and then the first transfer head 170 picks up red LED chips 101 on the first temporary substrate 30, the second transfer head 180 picks up green LED chips 601 on the second temporary substrate 80, and the third transfer head 190 picks up blue LED chips 1101 on the third temporary substrate 130 again. Then the rotating disk 150 is driven to rotate by a second angle counterclockwise (FIG. 26). After that, the rotating disk 150 is driven to move towards the display backplane 50, so that the first transfer head 170 transfers the red LED chips 101 to the third transfer region 503 of the display backplane 50, the second transfer head 180 transfers the green LED chips 601 to the fourth transfer region 504 of the display backplane 50, and the third transfer head 190 transfers the blue LED chips 1101 to the first transfer region 501 of the display backplane 50 (FIG. 27).

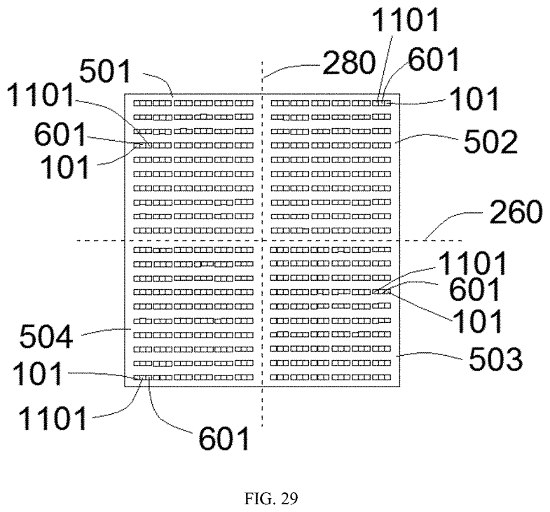

Referring to FIG. 28 to FIG. 29, the rotating disk 150 may be driven to reset again, and then the first transfer head 170 picks up red LED chips 101 on the first temporary substrate 30, the second transfer head 180 picks up green LED chips 601 on the second temporary substrate 80, and the third transfer head 190 picks up blue LED chips 1101 on the third temporary substrate 130 again. Then the rotating disk 150 is driven to rotate by a third angle counterclockwise (FIG. 28). After that, the rotating disk 150 is driven to move towards the display backplane 50, so that the first transfer head 170 transfers the red LED chips 101 to the fourth transfer region 504 of the display backplane 50, the second transfer head 180 transfers the green LED chips 601 to the first transfer region 501 of the display backplane 50, and the third transfer head 190 transfers the blue LED chips 1101 to the second transfer region 502 of the display backplane 50 (FIG. 29). In an implementation, the first angle is 90 degrees, the second angle is 180 degrees, and the third angle is 270 degrees. In one pixel area on each transfer region, a red LED chip 101 is adjacent to a green LED chip 601, a blue LED chip 1101 is adjacent to the green LED chip 601, and the green LED chip 601 is located between the red LED chip 101 and the blue LED chip 1101.

As such, after the above-described transfer processes, each transfer region has red, green, and blue chips thereon. The “transport” processes of these three types of chips to the four transfer regions only require four transfer processes, which greatly saves time of the mass transfer and facilitates mass production of the display.

It can be understood that the above is one round of transfer of the mass transfer apparatus, and the red, green, and blue chips can be transferred to a larger display backplane 50 by repeating the transfer processes. In this round of transfer, the mass transfer apparatus only needs to “transport” four times between the temporary substrates and the display backplane 50 to complete transfer of the red, green, and blue chips to the display backplane 50, which greatly saves time of the mass transfer and facilitates mass production of the display.

It can be understood that the first temporary substrate 30 may be made as follows. A first initial substrate 20 and a first growth substrate 10 are provided. Red LED chips 101 on the first growth substrate 10 are transferred to the first initial substrate 20 to form the first temporary substrate 30. For example, the first initial substrate 20 and the first growth substrate 10 are provided, where the first growth substrate 10 has multiple red LED chips 101 arranged thereon in an array. The first initial substrate 20 is stacked on the multiple red LED chips 101, such that the first initial substrate 20 picks up the multiple red LED chips 101 arranged in an array. The first growth substrate 10 is peeled off, so that the multiple red LED chips 101 arranged in an array and the first initial substrate 20 form the first temporary substrate 30.

The second temporary substrate 80 may be made as follows. A second initial substrate 70 and a second growth substrate 60 are provided. Green LED chips 601 on the second growth substrate 60 are transferred to the second initial substrate 70 to form the second temporary substrate 80. For example, the second initial substrate 60 and the second growth substrate 70 are provided, where the second growth substrate 60 has multiple green LED chips 601 arranged thereon in an array. The second initial substrate 70 is stacked on the multiple green LED chips 601, such that the second initial substrate 70 picks up the multiple green LED chips 601 arranged in an array. The second growth substrate 60 is peeled off, so that the multiple green LED chips 601 arranged in an array and the second initial substrate 70 form the second temporary substrate 80.

The third temporary substrate 130 may be made as follows. A third initial substrate 120 and a third growth substrate 110 are provided. Blue LED chips 1101 on the third growth substrate 110 are transferred to the third initial substrate 120 to form the third temporary substrate 130. For example, the third initial substrate 110 and the third growth substrate 120 are provided, where the third growth substrate 110 has multiple blue LED chips 1101 arranged thereon in an array. The third initial substrate 110 is stacked on the multiple blue LED chips 1101, such that the third initial substrate 120 picks up the multiple blue LED chips 1101 arranged in an array. The third growth substrate 110 is peeled off, so that the multiple blue LED chips 1101 arranged in an array and the third initial substrate 120 form the third temporary substrate 130.

In some embodiments, the mass transfer apparatus further includes a rotating component 270. The rotating component 270 is connected between the drive member 160 and the second surface 1502. The drive member 160 drives, through the rotating component 270, the rotating disk 150 to rotate. For example, a rotating rod is disposed inside the drive member 160 and connected with the rotating component 270. During rotation, the rotating rode inside the drive member 160 drives the rotating component 270 to rotate, thus driving the rotating disk 150 to rotate. The rotating component 270 is configured to transmit a torque of the drive member 160 to the rotating disk 150, so as to drive the rotating disk 150 to move or rotate. The drive member 160 includes a motor.

In some embodiments, the first transfer head 170 is movably connected with the first region A, the second transfer head 180 is movably connected with the second region B, and the third transfer head 190 is movably connected with the third region C. It can be understood that the first transfer head 170 is movable in the first region A, the second transfer head 180 is movable in the second region B, and the third transfer head 190 is movable in the third region C. For example, a position of the first transfer head 170 in the first region A may be manually adjusted, a position of the second transfer head 180 in the second region B may be manually adjusted, and a position of the third transfer head 190 in the third region C may be manually adjusted. Alternatively, the first transfer head 170 may be connected to the rotating disk through a slight-move element which is configured to slightly move the first transfer head 170 relative to the first region A. The second transfer head 180 may be connected to the rotating disk through a slightly-moving element which is configured to slightly move the second transfer head 180 relative to the second region B. The third transfer head 190 may be connected to the rotating disk through a slightly-moving element which is configured to slightly move the third transfer head 190 relative to the third region C. By adjusting the position of the first transfer head 170 in the first region A, the position of the second transfer head 180 in the second region B, and the position of the third transfer head 190 in the third region C, the first transfer head 170 may be controlled to accurately pick up red LED chips 101 on the first temporary substrate 30, the second transfer head 180 may be controlled to accurately pick up green LED chips 601 on the second temporary substrate 80, and the third transfer head 190 may be controlled to accurately pick up blue LED chips 1101 on the third temporary substrate 130. Moreover, the first transfer head 170 may be controlled to accurately transfer red LED chips 101 to the corresponding transfer region of the display backplane 50, the second transfer head 180 may be controlled to accurately transfer green LED chips 601 to the corresponding transfer region of the display backplane 50, and the third transfer head 190 may be controlled to accurately transfer blue LED chips 1101 to the corresponding transfer region of the display backplane 50.

In some embodiments, the first surface 1501 is symmetric about the first line 210 and the first surface 1501 is symmetric about the second line 220. That is, the first surface 1501 is central symmetric. The fire region A, the second region B, the third region C, and the fourth region D have a same shape, which is convenient for installation and arrangement of the first transfer head 170, the second transfer head 180, and the third transfer head 190. In one example, the first surface 1501 is circular or square.

In some embodiments, the first transfer head 170 has a first transfer surface 1701 away from the first surface 1501, the second transfer head 180 has a second transfer surface 1801 away from the first surface 1501, the third transfer head 190 has a third transfer surface 1901 away from the first surface 1501. The first transfer surface 1701, the second transfer surface 1801, and the third transfer surface 1901 have a same shape and area. In one example, the first transfer surface 1701 is configured to pick up red LED chips 101, the second transfer surface 1801 is configured to pick up green LED chips 601, and the third transfer surface 1901 is configured to pick up blue LED chips 1101. As such, each of the first transfer head 170, the second transfer head 180, and the third transfer head 190 can transfer the same number of chips each time. The number of chips transferred to the display backplane 50 can be accurately controlled, such that each transfer region has the same number of red, greed, and blue chips, thus improving yield of the display backplane 50.

In one example, the first transfer surface 1701 is square, the second transfer surface 1801 is square, and the third transfer surface 1901 is square.

In some embodiments, a first distance between a center of the first transfer head 170 and a center of the second transfer head 180 is equal to a second distance between the center of the second transfer head 180 and a center of the third transfer head 190. As such, after the rotating disk 150 rotates by a first angle, a second angle, or a third angle, the first transfer head 170, the second transfer head 180, and the third transfer head 190 can exchange positions with each other. Therefore, the first transfer head 170, the second transfer head 180, and the third transfer head 190 can align with corresponding transfer regions of the display backplane 50, thus improving accuracy of positions of chips and improving yield of the display backplane 50.

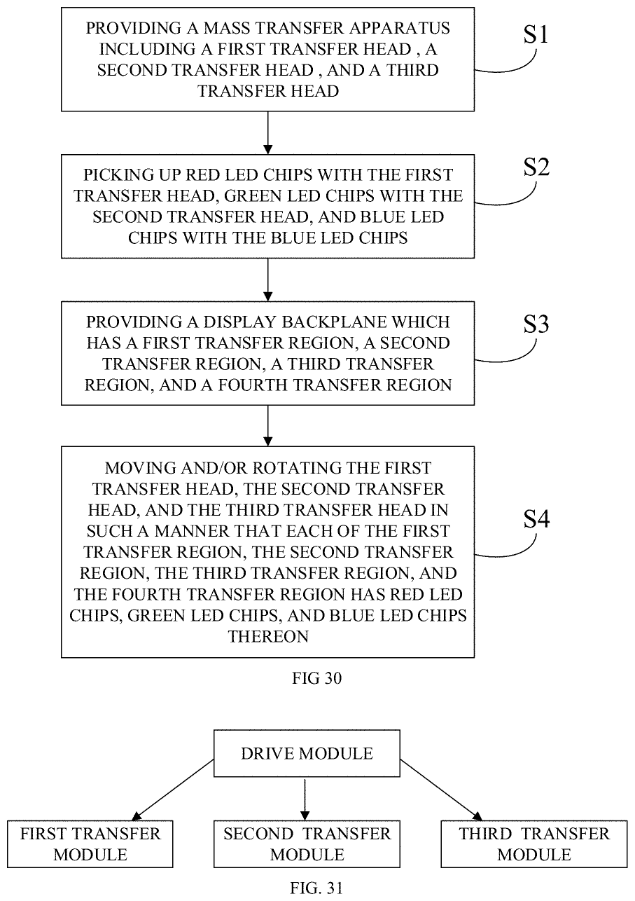

Referring to FIG. 30, in addition to the above-described mass transfer apparatus, the disclosure further provides a mass transfer method. The mass transfer method includes the following.

At S1, a mass transfer apparatus is provided. The mass transfer apparatus includes a first transfer head 170, a second transfer head 180, and a third transfer head 190.

At S2, red LED chips 101 are picked up with the first transfer head 170, green LED chips 601 are picked up with the second transfer head 180, and blue LED chips 1101 are picked up with the blue LED chips 1101. In one example, the operation at S2 includes operations at S21, S22, and S23.

At S21, a first temporary substrate 30, a second temporary substrate 80, and a third temporary substrate 130 are provided. The first temporary substrate 30 is provided with red LED chips 101 arranged thereon in an array, the second temporary substrate 80 is provided with green LED chips 601 arranged thereon in an array, the third temporary substrate 130 is provided with blue LED chips 1101 arranged thereon in an array.

At S22, the first transfer head 170, the second transfer head 180, and the third transfer head 190 are adjusted to align the first transfer head 170 with the first temporary substrate 30, align the second transfer head 180 with the second temporary substrate 80, and align the third transfer head 190 with the third temporary substrate 130.

At S23, the first transfer head 170 is driven to move towards the first temporary substrate 30, the second transfer head 180 is driven to move towards the second temporary substrate 80, and the third transfer head 190 is driven to move towards the third temporary substrate 130, such that the first transfer head 170 picks up the red LED chips 101 on the first temporary substrate 30, the second transfer head 180 picks up the green LED chips 601 on the second temporary substrate 80, and the third transfer head 190 picks up the blue LED chips 1101 on the third temporary substrate 130. According to the disclosure, before picking up the red, green, and blue LED chips, the first transfer head 170 is adjusted to be aligned with the first temporary substrate 30, the second transfer head 180 is adjusted to be aligned with the second temporary substrate 80, and the third transfer head 190 is adjusted to be aligned with the third temporary substrate 130. In this way, the first transfer head 170 can accurately pick up the red LED chips 101, the second transfer head 180 can accurately pick up the green LED chips 601, and the third transfer head 190 can accurately pick up the blue LED chips 1101.

At S3, a display backplane 50 is provided. The display backplane 50 has a first transfer region 501, a second transfer region 502, a third transfer region 503, and a fourth transfer region 504.

At S4, the first transfer head 170, the second transfer head 180, and the third transfer head 190 are moved and/or rotated in such a manner that each of the first transfer region 501, the second transfer region 502, the third transfer region 503, and the fourth transfer region 504 has red LED chips 101, green LED chips 601, and blue LED chips 1101 thereon.

In some embodiments, the mass transfer apparatus further includes a rotating disk 150. The first transfer head 170, the second transfer head 180, and the third transfer head 190 are disposed at a same side of the rotating disk 150 and spaced apart. The first transfer head 170, the second transfer head 180, and the third transfer head 190 are moved and/or rotated as follows. The rotating disk 150 is driven to move and/or rotate, so as to move and/or rotate the first transfer head 170, the second transfer head 180, and the third transfer head 190. The process of driving the rotating disk 150 to drive the first transfer head 170, the second transfer head 180, and the third transfer head 190 to move and/or rotate is simple and easy to implement.

As such, the mass transfer method of the disclosure uses the first transfer head 170, the second transfer head 180, and the third transfer head 190 to transfer the red LED chips 101, the green LED chips 601, and the blue LED chips 1101. In this way, transfer efficiency can be significantly improved, thus greatly saving time of the mass transfer and facilitating mass production of the display.

In some embodiments, the operation at S4 includes the following.

At S41, the first transfer head 170, the second transfer head 180, and the third transfer head 190 are driven to move towards the display backplane 50, such that the first transfer head 170 transfers the red LED chips 101 to the first transfer region 501 of the display backplane 50, the second transfer head 180 transfers the green LED chips 601 to the second transfer region 502 of the display backplane 50, and the third transfer head 190 transfers the blue LED chips 1101 to the third transfer region 503 of the display backplane 50. This operation at S41 is a first transfer process of the red LED chips 101, green LED chips 601, and blue LED chips 1101.

The operation at S4 further includes the following. At S42, the first transfer head 170, the second transfer head 180, and the third transfer head 190 are driven to rotate by a first angle counterclockwise. Then the first transfer head 170, the second transfer head 180, and the third transfer head 190 are driven to move towards the display backplane 50, such that the first transfer head 170 transfers the red LED chips 101 to the second transfer region 502 of the display backplane 50, the second transfer head 180 transfers the green LED chips 601 to the third transfer region 503 of the display backplane 50, and the third transfer head 190 transfers the blue LED chips 1101 to the fourth transfer region 504 of the display backplane 50. In one example, the first angle is 90 degrees.

In one example, before the first transfer head 170, the second transfer head 180, and the third transfer head 190 are rotated by the first angle, the first transfer head 170, the second transfer head 180, and the third transfer head 190 are driven to reset. Then the operation at S2 is repeated. That is, the first transfer head 170 is used to pick up red LED chips 101, the second transfer head 180 is used to pick up green LED chips 601, and the third transfer head 190 is used to pick up blue LED chips 1101. Afterwards, the first transfer head 170, the second transfer head 180, and the third transfer head 190 are rotated by the first angle counterclockwise. Then the first transfer head 170, the second transfer head 180, and the third transfer head 190 are driven to move towards the display backplane 50, such that the first transfer head 170 transfers the red LED chips 101 to the second transfer region 502 of the display backplane 50, the second transfer head 180 transfers the green LED chips 601 to the third transfer region 503 of the display backplane 50, and the third transfer head 190 transfers the blue LED chips 1101 to the fourth transfer region 504 of the display backplane 50. This operation at S42 is a second transfer process of the red LED chips 101, green LED chips 601, and blue LED chips 1101.

The operation at S4 further includes the following. At S43, the first transfer head 170, the second transfer head 180, and the third transfer head 190 are driven to rotate by a second angle counterclockwise. Then the first transfer head 170, the second transfer head 180, and the third transfer head 190 are driven to move towards the display backplane 50, such that the first transfer head 170 transfers the red LED chips 101 to the third transfer region 503 of the display backplane 50, the second transfer head 180 transfers the green LED chips 601 to the fourth transfer region 504 of the display backplane 50, and the third transfer head 190 transfers the blue LED chips 1101 to the first transfer region 501 of the display backplane 50.

In one example, before the first transfer head 170, the second transfer head 180, and the third transfer head 190 are rotated by the second angle, the first transfer head 170, the second transfer head 180, and the third transfer head 190 are driven to reset. Then the operation at S2 is repeated. That is, the first transfer head 170 is used to pick up red LED chips 101, the second transfer head 180 is used to pick up green LED chips 601, and the third transfer head 190 is used to pick up blue LED chips 1101. Afterwards, the first transfer head 170, the second transfer head 180, and the third transfer head 190 are rotated by the second angle counterclockwise. Then the first transfer head 170, the second transfer head 180, and the third transfer head 190 are driven to move towards the display backplane 50, such that the first transfer head 170 transfers the red LED chips 101 to the third transfer region 503 of the display backplane 50, the second transfer head 180 transfers the green LED chips 601 to the fourth transfer region 504 of the display backplane 50, and the third transfer head 190 transfers the blue LED chips 1101 to the first transfer region 501 of the display backplane 50. This operation at S43 is a third transfer process of the red LED chips 101, green LED chips 601, and blue LED chips 1101. In one example, the second angle is 180 degrees.

The operation at S4 further includes the following. At S44, the first transfer head 170, the second transfer head 180, and the third transfer head 190 are driven to rotate by a third angle counterclockwise. Then the first transfer head 170, the second transfer head 180, and the third transfer head 190 are driven to move towards the display backplane 50, such that the first transfer head 170 transfers the red LED chips 101 to the fourth transfer region 504 of the display backplane 50, the second transfer head 180 transfers the green LED chips 601 to the first transfer region 501 of the display backplane 50, and the third transfer head 190 transfers the blue LED chips 1101 to the second transfer region 502 of the display backplane 50.

In one example, before the first transfer head 170, the second transfer head 180, and the third transfer head 190 are rotated by the third angle, the first transfer head 170, the second transfer head 180, and the third transfer head 190 are driven to reset. Then the operation at S2 is repeated. That is, the first transfer head 170 is used to pick up red LED chips 101, the second transfer head 180 is used to pick up green LED chips 601, and the third transfer head 190 is used to pick up blue LED chips 1101. Afterwards, the first transfer head 170, the second transfer head 180, and the third transfer head 190 are rotated by the third angle counterclockwise. Then the first transfer head 170, the second transfer head 180, and the third transfer head 190 are driven to move towards the display backplane 50, such that the first transfer head 170 transfers the red LED chips 101 to the fourth transfer region 504 of the display backplane 50, the second transfer head 180 transfers the green LED chips 601 to the first transfer region 501 of the display backplane 50, and the third transfer head 190 transfers the blue LED chips 1101 to the second transfer region 502 of the display backplane 50. This operation at S44 is a fourth transfer process of the red LED chips 101, green LED chips 601, and blue LED chips 1101. In one example, the third angle is 270 degrees.

As such, using the mass transfer method of the disclosure, each transfer region may include red, green, and blue chips thereon. The “transport” process of these three types of chips to the four transfer regions only require four transfer processes, which greatly saves time of the mass transfer and facilitates mass production of the display.

The methods for forming the first temporary substrate 30, the second temporary substrate 80, and the third temporary substrate 130 are described above, which will not be repeated herein.

In some embodiments, each of the red LED chips 101 is axisymmetric, each of the green LED chips 601 is axisymmetric, and each of the blue LED chips 1101 is axisymmetric. As such, after the rotating disk 150 is rotated by the first angle, the second angle, and the third angle, the LED chips as rotated can be positioned on respective transfer regions smoothly without being skew or uneven.

Referring to FIG. 31, the disclosure further provides a mass transfer system. The mass transfer system includes a first transfer module 310, a second transfer module 320, and a third transfer module 330. The first transfer module 310 is configured to pick up red LED chips 101. The second transfer module 320 is configured to pick up green LED chips 601. The third transfer module 330 is configured to pick up blue LED chips 1101.

The mass transfer system further includes a drive module 340. The drive module 340 is configured to move and/or rotate the first transfer module 310, the second transfer module 320, and the third transfer module 330 in such a manner that each of a first transfer region 501, a second transfer region 502, a third transfer region 503, and a fourth transfer region 504 of a display backplane has red LED chips 101, green LED chips 601, and blue LED chips 1101 thereon.

It can be understood that the first transfer module 310 may be the first transfer head 170 above. The second transfer module 320 may be the second transfer head 180 above. The third transfer module 330 may be the third transfer head 190 above. The drive module 340 may be the drive member 160 above. The drive member may be an electrode.

The process of the drive module 340 driving the first transfer module 310, the second transfer module 320, and the third transfer module 330 to move and rotate to transfer the red, green, and blue chips is described in the foregoing, which will not be repeated herein.

As such, the mass transfer system of the disclosure uses the first transfer module 310, the second transfer module 320, and the third transfer module 330 to transfer the red LED chips 101, the green LED chips 601, and the blue LED chips 1101. In this way, transfer efficiency can be significantly improved, thus greatly saving time of the mass transfer and facilitating mass production of the display.

The disclosure provides a mass transfer device. The mass transfer device includes a first transfer head 170, a second transfer head 180, and a third transfer head 190. The first transfer head 170 is configured to pick up red LED chips 101. The second transfer head 180 is configured to pick up green LED chips 601. The third transfer head 190 is configured to pick up blue LED chips 1101.

The mass transfer device further includes a drive member 160. The drive member 160 is configured to move and/or rotate the first transfer head 170, the second transfer head 180, and the third transfer head 190 in such a manner that each of a first transfer region 501, a second transfer region 502, a third transfer region 503, and a fourth transfer region 504 of a display backplane 50 has red LED chips 101, green LED chips 601, and blue LED chips 1101 thereon.

The process of the drive member 160 driving the first transfer head 170, the second transfer head 180, and the third transfer head 190 to move and rotate to transfer the red, green, and blue chips is described in the foregoing, which will not be repeated herein.

As such, the mass transfer device of the disclosure uses the first transfer head 170, the second transfer head 180, and the third transfer head 190 to transfer the red LED chips 101, the green LED chips 601, and the blue LED chips 1101. In this way, transfer efficiency can be significantly improved, thus greatly saving time of the mass transfer and facilitating mass production of the display.

As such, the mass transfer apparatus and the mass transfer method of the disclosure significantly save time of the mass transfer and facilitate mass production of the display.

The above-disclosed are only some embodiments of the present disclosure, which cannot limit the scope of the present disclosure. Those of ordinary skill in the art can understand all or part of procedures for implementing the above-mentioned embodiments. The equivalent changes made according to the claims of the present disclosure still fall within the scope of the disclosure.

What is claimed is:

1. A mass transfer apparatus, comprising:
a rotating disk having a first surface and a second surface opposite to the first surface, wherein the first surface is divided by a first line and a second line perpendicular to the first line into a first region, a second region, a third region, and a fourth region arranged clockwise;
a drive member connected to the second surface and configured to drive the rotating disk to move or rotate; and
a first transfer head, a second transfer head, and a third transfer head, wherein the first transfer head is located in the first region, the second transfer head is located in the second region, and the third transfer head is located in the third region, wherein the first transfer head and the second transfer head are symmetric about the first line, and the second transfer head and the third transfer head are symmetric about the second line.

2. The mass transfer apparatus of claim 1, further comprising a rotating component, wherein the rotating component is connected between the drive member and the second surface and the drive member is configured to drive, through the rotating component, the rotating disk to rotate.

3. The mass transfer apparatus of claim 1, wherein the first transfer head is movably connected with the first region, the second transfer head is movably connected with the second region, and the third transfer head is movably connected with the third region.

4. The mass transfer apparatus of claim 1, wherein the first transfer head has a first transfer surface away from the first surface, the second transfer head has a second transfer surface away from the first surface, the third transfer head has a third transfer surface away from the first surface, and the first transfer surface, the second transfer surface, and the third transfer surface have a same shape and area.

5. The mass transfer apparatus of claim 4, wherein the first transfer surface is square, the second transfer surface is square, and the third transfer surface is square.

6. The mass transfer apparatus of claim 1, wherein a first distance between a center of the first transfer head and a center of the second transfer head is equal to a second distance between the center of the second transfer head and a center of the third transfer head.

7. The mass transfer apparatus of claim 1, wherein the first surface is symmetric about the first line and the first surface is symmetric about the second line.

8. The mass transfer apparatus of claim 1, wherein the first surface is circular or square.

9. A mass transfer method, comprising:
providing a mass transfer apparatus, the mass transfer apparatus comprising a first transfer head, a second transfer head, and a third transfer head;
picking up red LED chips with the first transfer head, green LED chips with the second transfer head, and blue LED chips with a third transfer head;
providing a display backplane, the display backplane having a first transfer region, a second transfer region, a third transfer region, and a fourth transfer region; and
moving and/or rotating the first transfer head, the second transfer head, and the third transfer head in such a manner that each of the first transfer region, the second transfer region, the third transfer region, and the fourth transfer region has red LED chips, green LED chips, and blue LED chips thereon.

10. The mass transfer method of claim 9, wherein picking up the red LED chip with the first transfer head, the green LED chip with the second transfer head, and the blue LED chip with a third transfer head comprises:
providing a first temporary substrate, a second temporary substrate, and a third temporary substrate, wherein the first temporary substrate is provided with red LED chips arranged thereon in an array, the second temporary substrate is provided with green LED chips arranged thereon in an array, the third temporary substrate is provided with blue LED chips arranged thereon in an array;
adjusting the first transfer head, the second transfer head, and the third transfer head to align the first transfer head with the first temporary substrate, align the second transfer head with the second temporary substrate, and align the third transfer head with the third temporary substrate; and
driving the first transfer head to move towards the first temporary substrate, the second transfer head to move towards the second temporary substrate, and the third transfer head to move towards the third temporary substrate, such that the first transfer head picks up the red LED chips on the first temporary substrate, the second transfer head picks up the green LED chips on the second temporary substrate, and the third transfer head picks up the blue LED chips on the third temporary substrate.

11. The mass transfer method of claim 9, wherein moving and/or rotating the first transfer head, the second transfer head, and the third transfer head in such a manner that each of the first transfer region, the second transfer region, the third transfer region, and the fourth transfer region has red LED chips, green LED chips, and blue LED chips comprises:
driving the first transfer head, the second transfer head, and the third transfer head to move towards the display backplane, such that the first transfer head transfers the red LED chips to the first transfer region of the display backplane, the second transfer head transfers the green LED chips to the second transfer region of the display backplane, and the third transfer head transfers the blue LED chips to the third transfer region of the display backplane.

12. The mass transfer method of claim 11, wherein moving and/or rotating the first transfer head, the second transfer head, and the third transfer head in such a manner that each of the first transfer region, the second transfer region, the third transfer region, and the fourth transfer region has red LED chips, green LED chips, and blue LED chips further comprises:
driving the first transfer head, the second transfer head, and the third transfer head to rotate by a first angle counterclockwise, and then driving the first transfer head, the second transfer head, and the third transfer head to move towards the display backplane, such that the first transfer head transfers the red LED chips to the second transfer region of the display backplane, the second transfer head transfers the green LED chips to the third transfer region of the display backplane, and the third transfer head transfers the blue LED chips to the fourth transfer region of the display backplane.

13. The mass transfer method of claim 12, wherein moving and/or rotating the first transfer head, the second transfer head, and the third transfer head in such a manner that each of the first transfer region, the second transfer region, the third transfer region, and the fourth transfer region has red LED chips, green LED chips, and blue LED chips further comprises:
driving the first transfer head, the second transfer head, and the third transfer head to rotate by a second angle counterclockwise, and then driving the first transfer head, the second transfer head, and the third transfer head to move towards the display backplane, such that the first transfer head transfers the red LED chips to the third transfer region of the display backplane, the second transfer head transfers the green LED chips to the fourth transfer region of the display backplane, and the third transfer head transfers the blue LED chips to the first transfer region of the display backplane.

14. The mass transfer method of claim 13, wherein moving and/or rotating the first transfer head, the second transfer head, and the third transfer head in such a manner that each of the first transfer region, the second transfer region, the third transfer region, and the fourth transfer region has red LED chips, green LED chips, and blue LED chips further comprises:
driving the first transfer head, the second transfer head, and the third transfer head to rotate by a third angle counterclockwise, and then driving the first transfer head, the second transfer head, and the third transfer head to move towards the display backplane, such that the first transfer head transfers the red LED chips to the fourth transfer region of the display backplane, the second transfer head transfers the green LED chips to the first transfer region of the display backplane, and the third transfer head transfers the blue LED chips to the second transfer region of the display backplane.

15. The mass transfer method of claim 9, wherein the mass transfer apparatus further comprises a rotating disk, the first transfer head, the second transfer head, and the third transfer head are disposed at a same side of the rotating disk and spaced apart, and wherein
moving and/or rotating the first transfer head, the second transfer head, and the third transfer head comprises: driving the rotating disk to move and/or rotate, so as to move and/or rotate the first transfer head, the second transfer head, and the third transfer head.

16. The mass transfer method of claim 10, further comprising:
providing a first initial substrate and a first growth substrate and transferring red LED chips on the first growth substrate to the first initial substrate to form the first temporary substrate;
providing a second initial substrate and a second growth substrate and transferring green LED chips on the second growth substrate to the second initial substrate to form the second temporary substrate; and
providing a third initial substrate and a third growth substrate and transferring blue LED chips on the third growth substrate to the third initial substrate to form the third temporary substrate.

17. The mass transfer method of claim 9, wherein each of the red LED chips is axisymmetric, each of the green LED chips is axisymmetric, and each of the blue LED chips is axisymmetric.

18. The mass transfer method of claim 14, wherein the first angle is 90 degrees, the second angle is 180 degrees, and the third angle is 270 degrees.

19. A mass transfer device, comprising:
a first transfer head configured to pick up red LED chips, a second transfer head configured to pick up green LED chips, and a third transfer head configured to pick up blue LED chips; and
a drive member configured to move and/or rotate the first transfer head, the second transfer head, and the third transfer head in such a manner that each of a first transfer region, a second transfer region, a third transfer region, and a fourth transfer region of a display backplane has red LED chips, green LED chips, and blue LED chips.

20. The mass transfer device of claim 19, further comprising a rotating disk, wherein the first transfer head, the second transfer head, and the third transfer head are movably connected with the rotating disk.
